(19) United States
(12) Patent Application Publication
(10) Pub. No.: US 2026/0122833 A1
(43) Pub. Date: Apr. 30, 2026

(54) SEMICONDUCTOR DEVICE WITH VOLTAGE REFERENCE AND TEST METHOD

(71) Applicant: Infineon Technologies AG, Neubiberg (DE)

(72) Inventor: Peter Bogner, Wernberg (AT)

(21) Appl. No.: 19/367,891

(22) Filed: Oct. 24, 2025

(30) Foreign Application Priority Data
Oct. 31, 2024 (DE) 102024210529.5

(51) Int. Cl. H05K 7/20

(52) U.S. Cl. CPC H05K 7/20

(57) ABSTRACT

A semiconductor device with voltage reference and test method is provided. In order to allow testing of a voltage reference 10 the voltage reference has an output 16 for outputting a temperature dependent voltage as well as an output 14 for the reference voltage. A heater 18 located on the semiconductor device adjacent to the voltage reference 10 for increasing the temperature of the voltage reference. A measurement circuit such as an analog to digital converter 20 is used to measure the temperature dependent voltage. A calculation unit 30 compares the change in the temperature dependent voltage at a plurality of temperatures and outputs an indication of an unsafe state if the change in the voltage falls outside a safe range.

### REFERENCE TO RELATED APPLICATION

This application claims priority to German Application number 102024210529.5, filed on Oct. 31, 2024, the contents of which are hereby incorporated by reference in their entirety.

### FIELD OF THE INVENTION

The invention relates to a semiconductor device with at least one voltage reference.

### BACKGROUND OF THE INVENTION

There is an increasing use of semiconductor chip such as microcontrollers in applications where safety is of importance. For example, in the Automotive sector, microcontrollers are increasingly being used in safety-critical functions. There is an automotive standard, defined in ISO 26262, which specifies various requirements in this regards.

In particular, a self check may be required. This may in instances be implemented by a redundant circuit so that there are at least two instances of the circuit; the outputs of the two instances can then be compared and action taken in case of a discrepancy. However, such an approach uses a lot of expensive chip area. There is accordingly a need for an alternative self-check technique.

In the event that the supply voltage to a chip falls below safe limits, then safe operation of the chip cannot be guaranteed. There is therefore in particular a need to evaluate whether the supply voltage falls in a safe range.

### SUMMARY OF THE INVENTION

According to a first example there is provided a semiconductor device comprising: a voltage reference comprising an output for outputting a reference voltage and a temperature dependent component generating a voltage that varies as a function of temperature; a heater located on the semiconductor device located adjacent to the voltage reference for increasing the temperature of the voltage reference; a measurement circuit connected to the output comparing the voltage across the temperature dependent component with the reference voltage; and a calculation unit connected to the measurement circuit and to the heater for controlling the heater to change the temperature and for comparing the change in the voltage across the temperature dependent component at a plurality of temperatures and outputting an indication of an unsafe state if the change in the voltage falls outside a safe range.

There is also provided a method of testing a semiconductor device, comprising: measuring the base-emitter voltage V_{BE,1} of the voltage reference in an initial state with the heater non-operational; operating the heater to raise the temperature of the voltage reference; measuring the base-emitter voltage V_{BE,2} is measured in the raised temperature state; calculating the difference in base emitter voltages ΔV_{BE}=V_{BE,2}−V_{BE,1}; and comparing the difference ΔV_{BE} in base emitter voltages with a predetermined range of base emitter voltages and signaling whether the difference is in the predetermined range to indicate if a fault may have occurred.

The inventor has realized that checking for a low supply voltage by comparing the supply voltage with a measured reference voltage only functions reliably if the reference voltage itself is correct. By using the above approach, the reliability of the reference itself can be checked.

The voltage reference may be a bandgap voltage reference. Such a bandgap voltage reference may include a plurality of bipolar transistors which act as a temperature dependent component with a voltage across the base and emitter that varies significantly as a function of temperature. Note that the output of the bandgap voltage reference itself is stable and only varies very slightly with temperature. This means that the variation in the voltage across the base and emitter of a bipolar transistor may be measured with reference to the voltage at the output of the bandgap voltage reference to provide a form of “self test” with limited additional components.

### BRIEF DESCRIPTION OF THE DRAWINGS

Examples of the invention will now be described, purely by way of example, with reference to the accompanying drawings, in which:

FIG. 1 shows a first example,

FIG. 2 shows a second example having two voltage references; and

FIG. 3 illustrates the sequence of steps used in the second example.

The drawings are purely schematic and not to scale.

### DETAILED DESCRIPTION

An example of the invention will be presented, purely by way of example. In Although specific embodiments/examples/aspects have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

A semiconductor device such as, for example, a microcontroller, has a bandgap reference 10 which contains a diode 12. This diode 12 may be the collector and emitter of the bandgap reference bipolar transistor. The bandgap reference has a bandgap output 14 for outputting the bandgap reference voltage and a diode voltage output 16 which outputs the voltage across the diode 12.

Both outputs 14, 16 are connected to an analogue to digital converter, ADC 20, which can measure the voltages and which has a digital output connected to calculation unit 30 which in turn has access to non-volatile memory 32. The calculation unit 30 may be a core processor of the microcontroller.

All components are supplied with power at a supply voltage 40.

A heater 18 is provided physically adjacent to the bandgap reference 10 on the chip for locally heating the bandgap reference 10. A heater controller 19 is provided connected to the heater 18 for controlling the heater, at least to switch it on and off and optionally to further control its output. The heater controller 19 may in turn be controlled by calculation unit 30.

In an initial test, which may be carried out during testing of the chip before installation, the base-emitter voltage V_{BE,1} is measured in an initial state with the heater non-operational and then the base-emitter voltage V_{BE,2} is measured in a heated state with the heater operational and hence with the diode 12 at a raised temperature.

The calculation unit 30 then calculates the difference in base-emitter voltages

$$Δ {V}_{BE} = {V}_{BE , 2} - {V}_{BE , 1}$$

and stores the resulting value in NVM 22.

In the field, a second test is carried out in the same way to obtain the difference in base-emitter voltages.

The value calculated in the field is then compared with the stored value and if it deviates by more than a predetermined amount an alarm is indicated.

The inventor has realized that in this way the correct functioning of the bandgap reference 10, the ADC 20 as well as the supply voltage 40, as failure in any of these will result in a discrepancy in the measured value.

Moreover, this is achieved simply with a heater 18 which can be implemented simply as a resistor and without requiring large additional area on the semiconductor device.

Referring to FIG. 2, an approach to checking in an arrangement with multiple units on chip is shown.

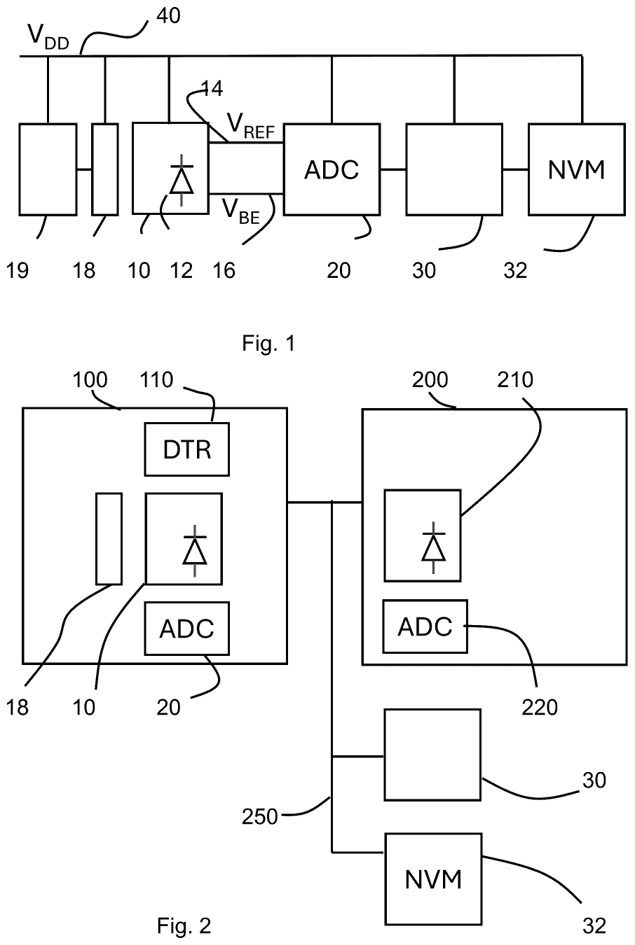

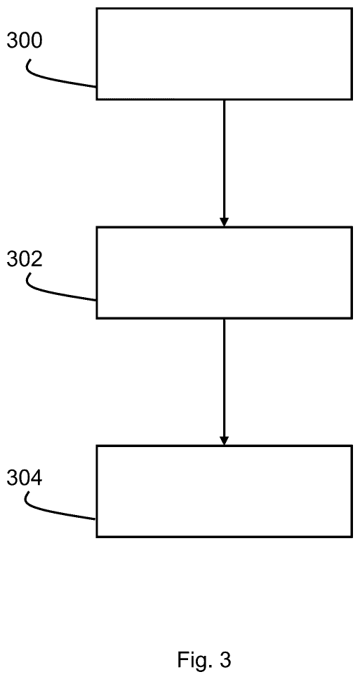

In this approach, the components illustrated in FIG. 1 are provided as a master 100 area of the semiconductor device. The master area 100 additionally comprises a die temperature sensor 110 adjacent to the bandgap device 10 and heater 18.

A satellite 200 area of the semiconductor device includes a further bandgap reference 210, and further ADC 220 but note that in this example there is no heater in the satellite area.

In this approach the calculation unit 30 and NVM 32 can be common and do not need to be located in the master or satellite areas 100,200. A bus 250 provides communication between the master 100, the satellite 200, the calculation unit 30 and the non-volatile memory 32.

In use, a comprehensive health check in the field is possible. Firstly, 300, the temperature of the bandgap reference 10 in the master area 100 is measured with the die temperature sensor 110. The voltage V_{BE,1} is also measured. Since the voltage V_{BE,1} is a function of temperature this measured voltage is used to calculate the temperature. This calculated temperature T₁ is compared with the temperature measured with the die temperature sensor 110 and in the event of a disparity an alarm is signaled.

Secondly, 302, the voltage V_{BE} is measured twice, once with the heater off V_{BE,1} and once with the heater on V_{BE,2}, and the difference value ΔV_{BE} calculated and compared with the reference value stored in the NVM 32 as described above with reference to FIG. 1. Again, in the event of a disparity an alarm is signaled.

Thirdly, 304, the voltage V_{BE,3} of the bandgap reference in the satellite is measured using ADC 220 and the temperature T₃ corresponding to this voltage V_{BE,3} calculated. As both the master area 100 and the satellite area 200 are on the same physical piece of silicon in this example, the temperatures T₁ and T₃ calculated from the respective bandgap voltages V_{BE,1} and V_{BE,3} should not deviate more than a further predetermined temperature difference ΔT from one another. In the case of a measured deviation of temperature greater than ΔT it is likely that there is an issue with one of the bandgap references 10, 210 and again an alarm may be signaled.

The checks may be carried out on startup of the semiconductor device, or during operation at regular intervals, or as required, or more than one of these options. In some cases, only some of the checks discussed in the previous paragraphs need be carried out.

Functional safety requires that the correct functioning of components is checked. If any bandgap reference does not work correctly then any measured voltages compared with that reference will also not be correct and accordingly the correct functioning of the bandgap reference is required for safety.

As discussed above with reference to FIG. 2, with a very limited number of additional components installed on the semiconductor device a check of more than one bandgap reference is possible. As above, also in the event that the supply voltage or ADC is not correct the alarm may be triggered.

Note that the same approach may be used for other voltage references as long as there is a measurable output voltage that is a function of temperature.

It should be noted that the examples as outlined in the present document may be used stand-alone or in combination with the other methods and systems disclosed in this document. In addition, the features outlined in the context of an apparatus are also applicable to a corresponding method, and vice versa. Furthermore, all aspects of the methods and apparatus outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiment outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

What is claimed is:

1. A semiconductor device comprising:
a voltage reference comprising
an output for outputting a reference voltage, and
a temperature dependent component for generating a voltage that varies as a function of temperature;
a heater located on the semiconductor device located adjacent to the voltage reference for increasing the temperature of the voltage reference;
a measurement circuit connected to the output configured to compare the voltage across the temperature dependent component with another voltage; and
a calculation unit connected to the measurement circuit and to the heater configured to
control the heater to change the temperature;
compare the change in the voltage across the temperature dependent component at a plurality of temperatures; and
output an indication of an unsafe state if the change in the voltage falls outside a safe range.

2. The semiconductor device according to claim 1 wherein the voltage reference is a bandgap voltage reference.

3. The semiconductor device according to claim 2 wherein the temperature dependent component is a bipolar transistor forming part of the bandgap voltage reference.

4. The semiconductor device of claim 1 wherein the measurement circuit is an analogue to digital converter with a voltage reference input that is connected to the output of the voltage reference.

5. The semiconductor device of claim 1 further comprising a die temperature sensor adjacent to the voltage reference.

6. The semiconductor device of claim 1, comprising a master area having a die temperature sensor, a bandgap reference, a heater arranged adjacent to the bandgap reference and an analog to digital converter, and a satellite area comprising a further bandgap reference and a further analog to digital converter.

7. The semiconductor device of claim 1, wherein the calculation unit is further configured to:
measure a base-emitter voltage V_{BE,1} of a voltage reference in an initial state with the heater non-operational;
operate the heater to raise the temperature of the voltage reference;
measure the base-emitter voltage V_{BE,2};
calculate the difference in base emitter voltages ΔV_{BE}=V_{BE,2}−V_{BE,1}; and
compare the difference in base emitter voltages ΔV_{BE} in base emitter voltages with a predetermined range of base emitter voltages and signaling whether the difference is in the predetermined range to indicate if a fault may have occurred.

8. The semiconductor device of claim 7, wherein the calculation unit is further configured to:
measure the temperature T_{DTS} of the semiconductor device using a die temperature sensor;
calculate a temperature T₁ from the measured base-emitter voltage V_{BE,1} of the voltage reference in the initial state; and
signal whether the measured temperature T_{DTS} and the calculated temperature T₁ deviate by more than a predetermined amount.

9. The semiconductor device of claim 8, wherein the calculation unit is further configured to:
measure the base-emitter voltage V_{BE,3} of a further voltage reference in a satellite area;
calculate a temperature T₃ from the further measured base-emitter voltage of the voltage reference V_{BE,3};
compare the difference between the calculated temperature T₁ from the measured base-emitter voltage V_{BE,1} of the voltage reference in the initial state and the calculated temperature T₃ from the further measured base-emitter voltage of the voltage reference V_{BE,3}; and
signal whether the difference is in the predetermined range to indicate if a fault may have occurred.

10. A method, comprising:
controlling a heater to operate in an operational or non-operational state, wherein the heater is located on a semiconductor device adjacent to a voltage reference and is configured to, when in the operational state, increase the temperature of the voltage reference;
with the heater in the non-operational state, measuring a first voltage across a temperature dependent component of the voltage reference;
with the heater in the operational state, measuring a second voltage across the temperature dependent component;
comparing the first voltage with the second voltage; and
outputting an indication of a fault condition based on a difference between the first voltage and the second voltage.

11. The method of claim 10, further comprising:
controlling the heater to operate in the non-operational state and measuring an first base-emitter voltage of the voltage reference;
controlling the heater to operation in the operational state and measuring a second base-emitter voltage of the voltage reference;
calculating the difference in the first base-emitter voltage and the second base-emitter voltage; and
determining the fault condition based on the difference.

12. The method of claim 11, further comprising comparing the difference with a predetermined difference in base-emitter voltages; and
signaling the fault when the difference falls outside the predetermined range.

13. The method of claim 11, further comprising
measuring a first temperature of the semiconductor device;
calculating second temperature based on the first base-emitter voltage; and
determining the fault condition based on a difference between the first temperature and the second temperature.

14. The method of claim 11, further comprising
measuring a satellite base-emitter voltage of a further voltage reference in a satellite area;
calculating a third temperature based on the satellite base-emitter voltage; and
determining the fault condition based on a difference between the third temperature and the first temperature.

15. A semiconductor device, comprising:
a voltage reference configured to generate a reference voltage, the voltage reference comprising a temperature dependent component that generates a voltage that varies as a function of temperature;
a heater located on the semiconductor device located adjacent to the voltage reference, wherein the heater is configured to, when in an operational state, increase the temperature of the voltage reference;
a measurement circuit connected to the temperature dependent component and configured to measure the voltage across the temperature dependent component; and
a calculation unit connected to the measurement circuit and to the heater, the calculation unit configured to
control the heater to operate in a non-operational state and measure a first voltage across the temperature dependent component;
control the heater to operate in the operational state and measure a second voltage across the temperature dependent component;
compare the first voltage with the second voltage; and
output an indication of a fault condition based on a difference between the first voltage and the second voltage.

16. The semiconductor device of claim 15, wherein the calculation unit is configured to
control the heater to operate in the non-operational state and measuring an first base-emitter voltage of the voltage reference;
control the heater to operation in the operational state and measuring a second base-emitter voltage of the voltage reference;
calculate the difference in the first base-emitter voltage and the second base-emitter voltage; and
determine the fault condition based on the difference.

17. The semiconductor device of claim 16, wherein the calculation unit is configured to
compare the difference with a predetermined difference in base-emitter voltages; and
signal the fault when the difference falls outside the predetermined range.

18. The semiconductor device of claim 16, wherein the calculation unit is configured to
measure a first temperature of the semiconductor device;
calculate second temperature based on the first base-emitter voltage; and
determine a fault condition based on a difference between the first temperature and the second temperature.

19. The semiconductor device of claim 18, wherein the calculation unit is configured to
measure a satellite base-emitter voltage of a further voltage reference in a satellite area;
calculate a third temperature based on the satellite base-emitter voltage; and
determine a fault condition based on a difference between the third temperature and the first temperature.
